(19) United States
(12) Patent Application Publication
(10) Pub. No.: US 2025/0157847 A1
(43) Pub. Date: May 15, 2025

(54) SYSTEMS AND METHODS FOR BOND TREATING AND CLEAVING OF SILICON WAFERS

(71) Applicant: GlobalWafers Co., Ltd., Hsinchu (TW)

(72) Inventors: Peter Albrecht, O'Fallon, MO (US); Qingmin Liu, Glen Carbon, IL (US); William L. Luter, St. Charles, MO (US); Benjamin Michael Meyer, Defiance, MO (US); Vandan Tanna, O'Fallon, MO (US); James Dean Eoff, Montgomery City, MO (US); Benno Orschel, Frontenac, MO (US); Yu-Chiao Wu, Frontenac, MO (US); Markus Jan Peter Siegert, Key West, FL (US); Michael Ogle, Wildwood, MO (US)

(21) Appl. No.: 18/505,496

(22) Filed: Nov. 9, 2023

(51) Int. Cl. H01L 21/687; H01L 21/67; H01L 21/762

(52) U.S. Cl. CPC H01L 21/68707; H01L 21/67092; H01L 21/76254

(57) ABSTRACT

A semiconductor wafer processing system for processing a set of semiconductor wafers includes a bond treat station including an oven, a cleave station including a cleave assembly for cleaving the wafer, a transfer robot, and a controller for controlling the transfer robot. The controller is programmed to control the transfer robot to retrieve a first wafer of the set of semiconductor wafers from the bond treat station and control the transfer robot to deliver the first wafer to the cleave station for processing by the cleave assembly.

### FIELD

The field generally relates to the production of silicon on insulator structures, and more specifically, to systems and methods for automated bond treatment and cleaving of silicon on insulator wafers.

### BACKGROUND

Semiconductor wafers are generally prepared from a single crystal ingot (e.g., a silicon ingot) which is trimmed and ground to have one or more flats or notches for proper orientation of the wafer in subsequent procedures. The ingot is then sliced into individual wafers. While reference will be made herein to semiconductor wafers constructed from silicon, other materials may be used to prepare semiconductor wafers, such as germanium, silicon carbide, silicon germanium, or gallium arsenide.

Semiconductor wafers (e.g., silicon wafers) may be utilized in the preparation of composite layer structures. A composite layer structure (e.g., a semiconductor-on-insulator, and more specifically, a silicon-on-insulator (SOI) structure) generally includes a handle wafer or layer, a device layer, and an insulating (i.e., dielectric) film (typically an oxide layer) between the handle layer and the device layer. Generally, the device layer is between 0.01 and 20 micrometers thick, such as between 0.05 and 20 micrometers thick. In general, composite layer structures, such as silicon-on-insulator (SOI), silicon-on-sapphire (SOS), and silicon-on-quartz, are produced by placing two wafers in intimate contact, followed by a thermal treatment to strengthen the bond.

After thermal anneal, the bonded structure undergoes further processing to remove a substantial portion of the donor wafer to achieve layer transfer. For example, wafer thinning techniques, e.g., etching or grinding, may be used, often referred to as back etch SOI (i.e., BESOI), wherein a silicon wafer is bound to the handle wafer and then slowly etched away until only a thin layer of silicon on the handle wafer remains. See, e.g., U.S. Pat. No. 5,189,500, the disclosure of which is incorporated herein by reference as if set forth in its entirety. This method is time-consuming and costly, wastes one of the substrates, and generally does not have suitable thickness uniformity for layers thinner than a few microns.

Another common method of achieving layer transfer utilizes a hydrogen implant followed by thermally induced layer splitting. Particles (e.g., hydrogen atoms or a combination of hydrogen and helium atoms) are implanted at a specified depth beneath the front surface of the donor wafer. The implanted particles form a cleave plane in the donor wafer at the specified depth at which they were implanted. The surface of the donor wafer is cleaned to remove organic compounds deposited on the wafer during the implantation process.

The front surface of the donor wafer is then bonded to a handle wafer to form a bonded wafer through a hydrophilic bonding process. Prior to bonding, the donor wafer and/or handle wafer may be activated by exposing the surfaces of the wafers to plasma containing, for example, oxygen or nitrogen. Exposure to the plasma modifies the structure of the surfaces in a process often referred to as surface activation, which activation process renders the surfaces of one or both of the donor water and handle wafer hydrophilic. The wafers are then pressed together, and a bond is formed there between. This bond may be relatively weak and may be strengthened before further processing occurs.

In some processes, the hydrophilic bond between the donor wafer and handle wafer (i.e., a bonded wafer) is strengthened by heating or annealing the bonded wafer pair. In some processes, wafer bonding may occur at low temperatures, such as between approximately 300° C. and 500° C. In some processes, wafer bonding may occur at high temperatures, such as between approximately 800° C. and 1100° C. The elevated temperatures cause the formation of covalent bonds between the adjoining surfaces of the donor wafer and the handle wafer, thus solidifying the bond between the donor wafer and the handle wafer. Concurrently with the heating or annealing of the bonded wafer, the particles earlier implanted in the donor wafer weaken the cleave plane.

A portion of the donor wafer is then separated (e.g., cleaved) along the cleave plane from the bonded wafer to form the SOI wafer. Cleaving may be carried out by placing the bonded wafer in a fixture in which mechanical force is applied perpendicular to the opposing sides of the bonded wafer in order to pull a portion of the donor wafer apart from the bonded wafer. According to some methods, suction cups and in some cases also springs are utilized to apply the mechanical force. The separation of the portion of the donor wafer is initiated by applying a mechanical wedge at the edge of the bonded wafer at the cleave plane in order to initiate propagation of a crack along the cleave plane. The mechanical force applied by the suction cups and springs along with the arm rotation then pulls the upper wafer (donor) apart from the lower wafer (handle) at a speed that allows the separation included by the wedge to propagate uninterrupted, thus forming an SOI wafer.

According to other methods, the bonded pair may instead be subjected to an elevated temperature over a period of time to separate the portion of the donor wafer from the bonded wafer.

In some systems and methods, operator-controlled transfers are used to move the wafers after bond treatment to be cleaved. For example, the bond treating of the wafers may be performed by a first machine and the cleaving of the wafers may be performed by a second independent machine. In such systems, the wafers are loaded and unloaded into the separate machines and transferred between the machines manually (i.e., by an operator). Such systems provide a manual work in process between the machines that is subject to variability between different batches of processed wafers. As an example, changing shifts of operators in a facility may impact the amount of time wafers are held between bond treatment and cleaving machines.

Thus, there is a need for improved control over operations related to bond treating and cleaving SOI wafers.

This background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect is directed to a semiconductor wafer processing system for processing a set of semiconductor wafers. The system includes a bond treat station including an oven, a cleave station including a cleave assembly for cleaving the wafer, a transfer robot, and a controller for controlling the transfer robot. The controller is programmed to control the transfer robot to retrieve a first wafer of the set of semiconductor wafers from the bond treat station and control the transfer robot to deliver the first wafer to the cleave station for processing by the cleave assembly.

Another aspect is directed to a method for processing a set of semiconductor wafers. The method includes retrieving, by a transfer robot, a first bonded pair wafer of the set of semiconductor wafers from a bond treat station, where the bond treat station including an oven. The method further includes delivering, by the transfer robot, the first bonded pair wafer to a cleave station, the cleave station including a cleave assembly. The method further includes cleaving, by the cleave assembly, the first bonded pair wafer.

Various refinements exist of the features and steps noted in relation to the above aspects. Further features may also be incorporated in the above-mentioned aspect as well. These refinements and additional features may exist individually or in any combination. For instance, various features and steps discussed below in relation to any of the illustrated embodiments may be incorporated into the above-described aspect, alone or in any combination.

### BRIEF DESCRIPTION OF THE DRAWINGS

FIG. 1 is block diagram of a processing system for bond treating and cleaving silicon wafers.

FIG. 2 is a schematic perspective view of the processing system of FIG. 1.

FIG. 3 is a schematic top view of a bond treat station of the processing system of FIG. 1.

FIG. 4 is a schematic side view of a queueing robot of the processing system of FIG. 3.

FIG. 5 is a schematic perspective view of a portion of the queueing robot of FIG. 4.

FIG. 6 is another schematic perspective view of a portion of the queueing robot of FIG. 4.

FIG. 7 is a schematic side view of a cleave station of the processing system of FIG. 1.

FIG. 8 is a flow diagram of an example method of processing silicon wafers using the processing system of FIG. 1.

FIG. 9 is a schematic showing a step in the method of FIG. 8 in which the transfer robot engages a wafer from a wafer pod.

FIG. 10 is a schematic showing a step in the method of FIG. 8 in which the transfer robot loads the wafer into a cassette.

FIG. 11 is a schematic showing a step in the method of FIG. 8 in which the transfer robot loads all wafers from the wafer pod into the cassette.

FIG. 12 is a schematic showing the queueing robot and the oven of FIG. 1, with a first arm of the queueing robot in a vertical orientation.

FIG. 13 is a schematic showing the queueing robot and the oven of FIG. 12, with the first arm of the queueing robot in a horizontal orientation.

FIG. 14 is a schematic showing the queueing robot and the oven of FIG. 12, with a carriage of the queueing robot in an extended position.

FIG. 15 is a schematic showing the queueing robot and the oven of FIG. 12, with the carriage in a retracted position.

FIG. 16 is a schematic showing the queueing robot and the oven of FIG. 12 in a step of the method of FIG. 8, in which the transfer robot picks up a bond treated wafer from the cassette.

FIG. 17 is another schematic showing a step of the method of FIG. 8, in which the transfer robot picks up a bond treated wafer from the cassette.

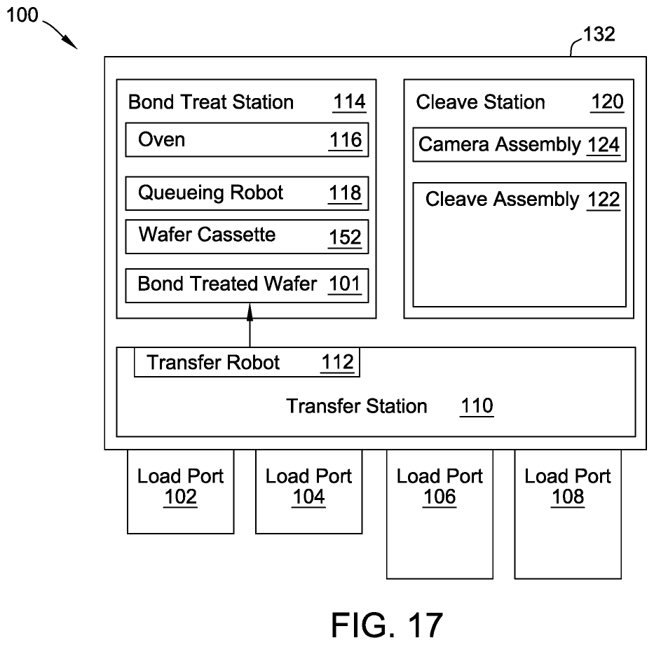

FIG. 18 is a schematic showing a step of the method of FIG. 8, in which the transfer robot deposits the bond treated wafer at a cleave assembly of the cleave station.

FIG. 19 is another schematic showing a step of the method of FIG. 8, in which the transfer robot picks up a handle wafer from the cleave assembly.

Like reference symbols in the various drawings indicate like elements.

### DETAILED DESCRIPTION

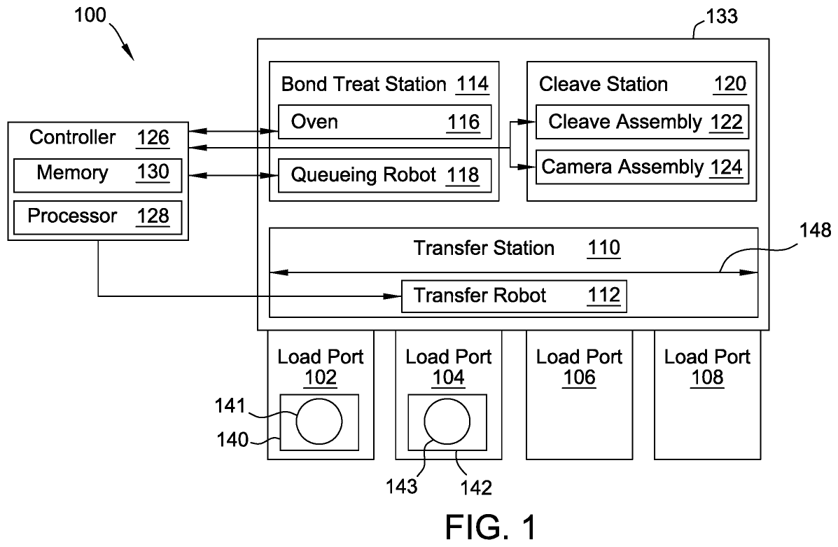

A block diagram of a semiconductor wafer processing system 100 for processing a set of semiconductor wafers is illustrated schematically in FIG. 1. The processing system 100 includes load ports 102, 104, 108, 110, a transfer station 110 including a transfer robot 112, a bond treat station 114 including an oven 116 (alternatively referred to as a “furnace”) and a queueing robot 118, a cleave station 120 including a cleave assembly 122 and a camera assembly 124. The system 100 further includes a controller 126 that includes a processor 128 and a memory 130. In the example, the processing system 100 includes four load ports 102, 104, 108, 110, though in other embodiments any number of load ports 102, 104, 108, 110 may be used. The load ports 102, 104, 108, 110, the transfer station 110, and the cleave station 120 are each positioned at least partially within a machine frame 133.

The controller 126 communicates with at least each of the oven 116, the queueing robot 118, the cleave assembly 122, the camera assembly 124, and the transfer robot 112. The controller 126 automates the transferring of wafers from the bond treat station 114 to the cleave station 120 for individualized cleaving of the wafers. As a result, the system reduces manual operations between bond treating of the wafers and cleaving of the wafers, thereby reducing the potential for delay between bond treating and cleaving of the wafers.

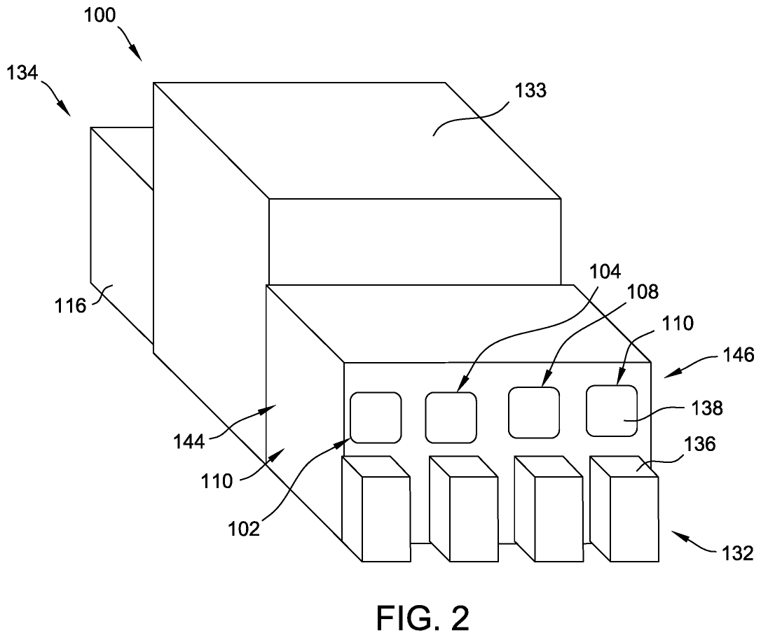

FIG. 2 is schematic view of the processing system 100 shown in FIG. 1. As shown in FIG. 2, the processing system 100 includes a machine frame 133 that extends over (and obscures from view in FIG. 2), the cleave station 120 and a portion of the bond treat station 114 (shown in FIG. 1). The load ports 102, 104, 108, 110 are positioned at a front end 132 of the system 100 and the oven 116 is positioned at a rear end 134 of the system 100 and extends outward of the machine frame 133.

The load ports 102, 104, 108, 110 of the processing system 100 are laterally spaced from one another along the front end 132 of the processing system 100. Each of the load ports 102, 104, 108, 110 includes a load platform 136 and a load door 138. The load door 138 selectively opens or closes to receive wafers (not shown) on the load platforms 136 therethrough. The load platforms 136 extend outward from the respective load doors 138 at the front end 132 of the processing system 100.

The transfer station 110 is positioned rearward of the load ports 102, 104, 108, 110 and forward of the cleave station 120 and the bond treat station 114 (shown in FIG. 1). The transfer station 110 extends from a first side 144 to a second side 146 of the system 100.

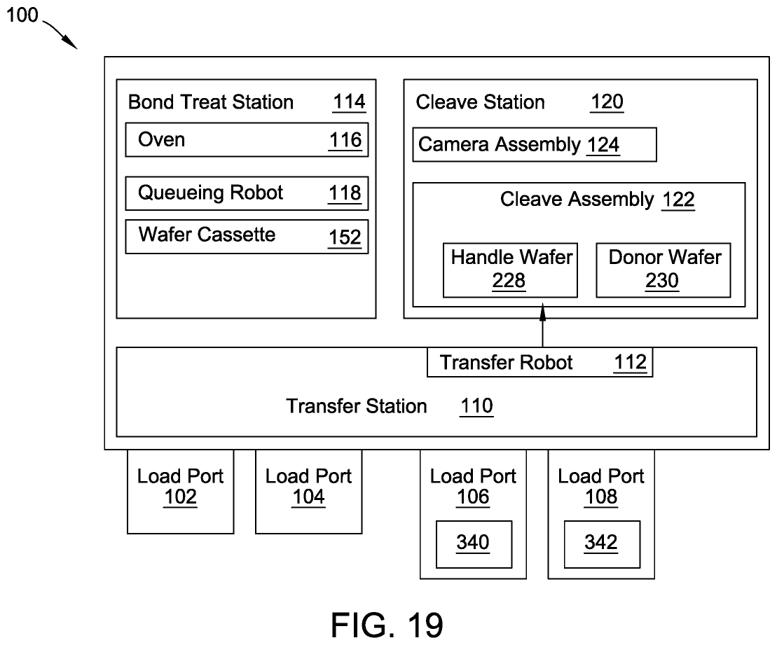

Referring back to FIG. 1, during use, wafers to be processed are positioned within front opening unified pods 140, 142 (“FOUP”), also referred to herein as “pods” or “wafer pods.” In other embodiments, the pods 140, 142 are shipping boxes, such as a front opening shipping box” (“FOSB”). The wafer pods 140, 142 are received at one of the first and second load ports 102, 104 (collectively referred to herein as “load-in” ports) and, after being processed by the processing system, the wafers are deposited within wafer pods 340, 342 (e.g., as shown in FIG. 19) at the third and fourth load ports 106, 108 (collectively referred to as “load-out” ports). Any of the ports 102, 104, 108, 110 may be used for loading and/or unloading of wafer pods 140, 142, 340, 342.

As shown in FIG. 1, a first set of wafers 141 are positioned within a first pod 140 at the first load port 102 and a second set of wafers 143 are positioned within a second pod 142 at the second load port 104. In other embodiments, the processing system 100 may include any number of load ports and, in some embodiments, the load-in ports may be positioned on a different side or end of the system 100 from the load-out ports. For example, in some embodiments, the load-in ports are positioned at an opposed end of the system 100 from the load-out ports 102, 104, 108, 110.

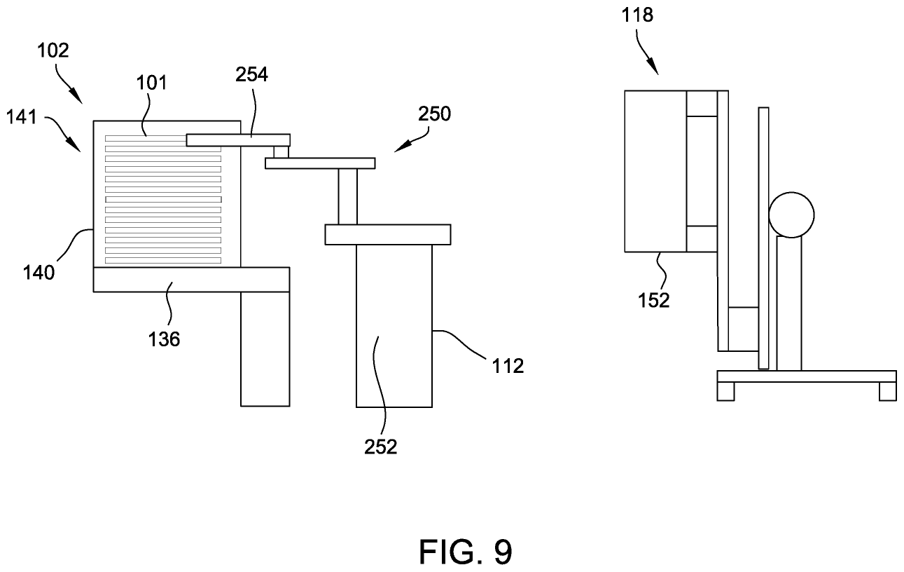

The transfer robot 112 is positioned within the machine frame 133 at the transfer station 110. The transfer robot 112 is an automated vehicle that is movable along a path of movement, indicated at 148, that extends laterally of the system 100 from the first side 144 to the second side 146 (shown in FIG. 2). The transfer robot 112 further includes an end effector 254 (shown in FIG. 9) for picking-up and depositing the wafers. In some embodiments, the transfer station 110 may also include a notch aligner and a laser mark reader (not shown).

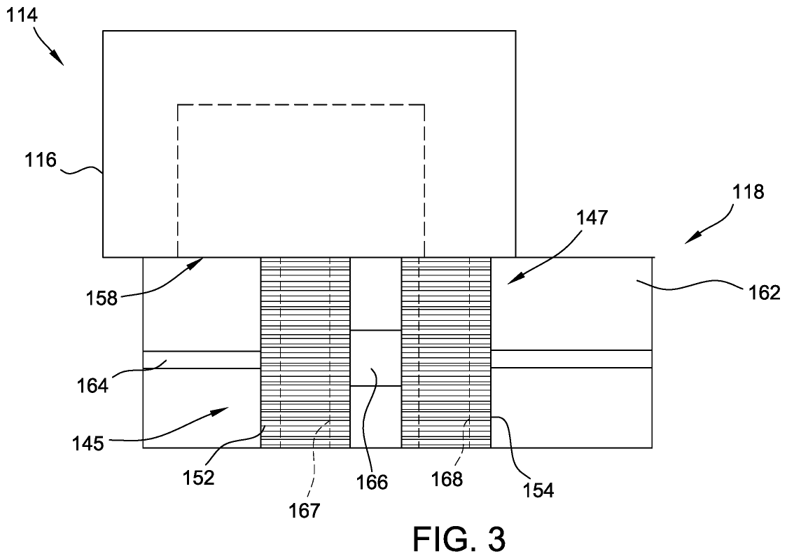

FIG. 3 is a top schematic view of the bond treat station 114. The queueing robot 118 is positioned adjacent to the oven 116 for loading and unloading of wafer cassettes 152, 154 (alternatively referred to as “wafer boats”) into the oven 116. The oven 116 includes an oven door (not shown) that is able to selectively raise and lower to expose an opening 158 provide access to an interior 160 of the oven 116.

The wafers 145, 147 are bonded pair wafers that include a handle portion and a donor portion. The oven 116 provides a bond treatment to wafers loaded within the oven 116. The bond treatment causes ions implanted within the bonded wafer pairs to form platelets that create stress in a cleave plane of the wafers, to prepare them for cleaving.

The queueing robot 118 includes a base frame 162 and a track 164 attached to the base frame 162. A support slide 166 is slidably connected or slidably attached to the track 164. The queueing robot 118 further includes a first cassette arm 167 for holding a first wafer cassette 152 and a second cassette arm 168 for holding a second wafer cassette 154. In FIG. 3, the first cassette arm 167 and second cassette arm 168 are each shown in dashed lines to indicate that they are at least partially obstructed by the wafer cassettes 152, 154.

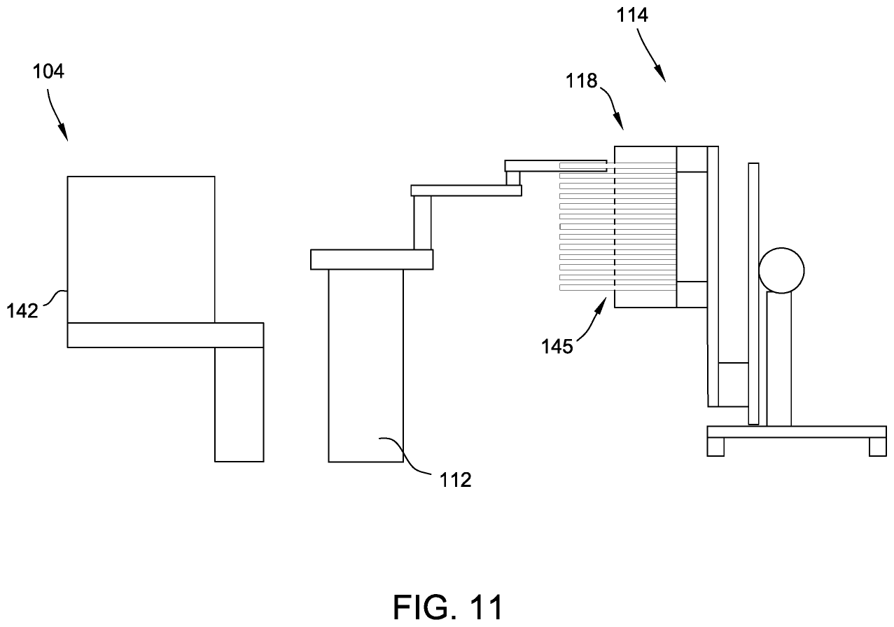

The wafer cassettes 152, 154 are each sized to hold a set of wafers 145, 147 therein in a stacked position. The cassettes 152, 154 each include a set of rungs (not shown) which the wafers 145, 147 are each positioned on such that the wafers 145, 147 are each spaced from and do not contact adjacent stacked wafers 145, 147 when received in the cassettes 152, 154. The cassettes 152, 154 are substantially identical to one another and are each shaped to support the wafers therein in a horizontal configuration (e.g., as in FIG. 3), a vertical configuration (e.g., as shown in FIG. 11), and a plurality of positions between the vertical configuration and the horizontal configuration.

The first cassette arm 167 and the second cassette arm 168 are each pivotably connected to the support slide 166 and are operable to rotate independently of one another between the horizontal configuration and the vertical configuration. The support slide 166 is moveable along the track 164 to position either one of the cassette arms 167, 168 in alignment with the opening 158 to the oven interior 160.

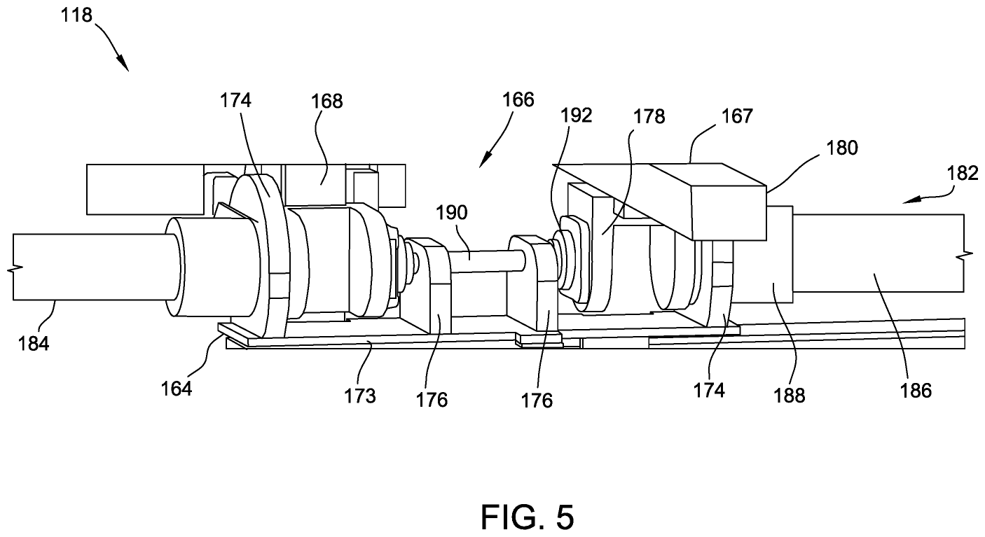

Each of the wafer cassettes 167, 168 are sized to hold fifty wafers and the pods (shown in FIG. 1) are sized to hold twenty-five wafers. During use, the transfer robot 112 loads the first set of wafers 141 from the first wafer pod 140 at the load port 102 (shown in FIG. 1) and the second set of wafers 143 from the pod 142 into one of the wafer cassettes 152, 154 oriented in the vertical configuration. For example, when both wafer cassettes 152, 154 are initially empty, the transfer robot 112 may begin loading wafers 141 into the first cassette 152 in the vertical configuration. In FIG. 5, the set of wafers 145 on the first cassette 152 includes both the first set of wafers 141 and the second set of wafers 143 shown in FIG. 1.

After the first cassette 152 is loaded, the support slide 166 is moved along the track 164 to align the first cassette arm 167 with the opening 158 to the oven interior 160, if the first cassette arm 167 is not already aligned. The first cassette arm 167 is then rotated to the horizontal configuration, as shown in FIG. 3, for loading the cassette 152 into the oven 116. While the first wafer cassette 152 is being processed in the oven, the second cassette 154 may also be loaded with wafers in substantially the same manner as described with respect to the first cassette 152.

After the wafers 145 in the first cassette 152 are finished processing in the oven (e.g., as determined by the elapsing of a predetermined time period), the oven door 156 is opened and the first cassette arm 167 is moved in the horizontal configuration to remove the first cassette 152 from the oven 116. The first cassette arm 167 is then rotated to the vertical configuration and the support slide 166 is moved to align the second cassette arm 168 with the oven opening 158. The second wafer cassette 154 is then loaded into the oven 116 in substantially the same manner as the first wafer cassette 152 (e.g., by pivoting the second cassette arm 168 to the horizontal configuration and sliding the second wafer cassette 154 into the oven). While the wafers 147 in the second wafer cassette 154 are processed in the oven 116, and optionally after a predetermined time period for cooling the bond treated wafers 145 has elapsed, the wafers 145 from the first wafer cassette 152 may be individually transported by the transfer robot 112 to the cleaving station 120 for processing by the cleave assembly 122, as described in greater detail below.

After and/or in conjunction with moving the bond treated wafers to the cleaving station 120, untreated wafers from the load ports 102, 104, 108, 110 may be added to the first wafer cassette 152, filling slots in the first wafer cassette 152 that are emptied by the removal treated wafers. In some embodiments, by the time the second wafer cassette 154 is finished processing in the oven 116, all of the treated wafers may have been removed from the first cassette 152 and replaced with untreated wafers, such that the first cassette 152 is ready to be loaded back into the oven 116. As a result, the bond treat station 114 is able to continuously process cassettes of wafers 145, 147 in the oven 116, thereby reducing a downtime of the oven 116 for unloading and refilling the cassettes 152, 154 between processing. In other embodiments, the queueing robot 118 may include any number of wafer cassette arms 167, 168 such as, for example, one wafer cassette arm.

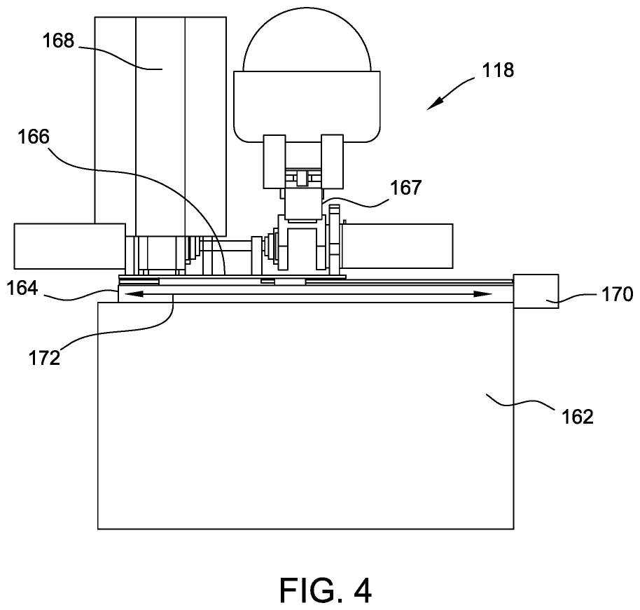

Referring to FIG. 4, the queueing robot 118 further includes a lateral motor 170 attached to the track 164 and operably connected to the support slide 166. The lateral motor 170 is a servomotor that is actuated to move the support slide 166 on the track 164 along a lateral path of movement, indicated at 172. The first cassette arm 167 and the second cassette arm 168 are each connected to the track 164 by the support slide 166 such that movement of the support slide 166 on the track 164 moves both the first cassette arm 167 and the second cassette arm 168. In other embodiments, the first cassette arm 167 and the second cassette arm 168 may be independently connected to the track 164 and/or one or more additional tracks (not shown) such that the arms 167, 168 may be moved laterally independently of one another.

Referring to FIG. 5, the support slide 166 includes a support slide base 173, a pair of outer brackets 174, and a pair of inner brackets 176 each positioned between the pair of outer brackets 174. Each of the brackets 174, 176 extend vertically from the support slide base 173. The first cassette arm 167 and the second cassette arm 168 each include a base mount 178 and an arm body 180 (or “rail”) attached to the base mount 178.

The queueing robot 118 further includes a first arm drive 182 connected to the first cassette arm 167 and a second arm drive 184 connected to the second cassette arm 168. The first arm drive 182 includes a pivot motor 186 (e.g., a servomotor) and a gear box 188 connected to the pivot motor 186. The gear box 188 is attached to the base mount 178 and connects the pivot motor 186 to the base mount 178 of the first cassette arm 167. The gear box 188 has a 1000:1 gear ratio, though in other embodiments, the gear box 188 may have any suitable gear ratio. The second arm drive 184 is substantially identical to the first arm drive 182.

The queueing robot 118 includes a central shaft 190 supported above the support slide base 173 by the inner brackets 176 and extending through apertures (not shown) defined within the inner brackets 176. The first cassette arm 167 and the second cassette arm 168 are each mounted on the central shaft 190 and are rotatable thereon. In particular, referring to the first cassette arm 167, the central shaft 190 is connected to the base mount 178 by a bearing mount 192 attached to the base mount 178. During use, when the pivot motor 186 is actuated, the base mount 178 is rotated on the central shaft 190, causing the first cassette arm 167 to rotate between the horizontal and vertical configurations shown in FIG. 3. The second cassette arm 168 is connected to the central shaft 190 in substantially the same manner, with the second cassette arm 168 being rotatable on the central shaft 190. As a result, the first cassette arm 167 and the second cassette arm 168 are each rotatable on the shaft 190 independent of one another.

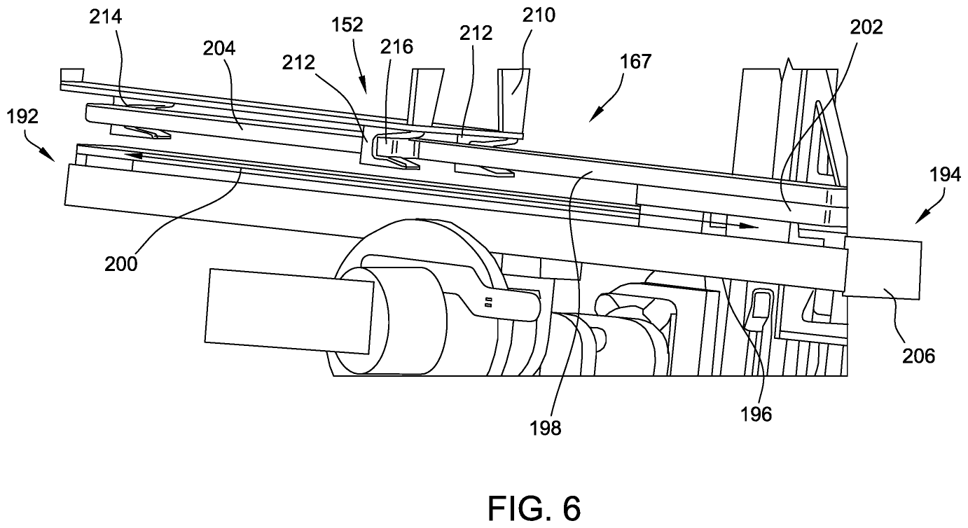

Referring to FIG. 6, the first cassette arm 167 extends between a first end 192 and a second opposed end 194. The first cassette arm 167 includes a cassette track 196 and a cassette carriage 198 that is slidably connected to and supported by the cassette track 196. The carriage 198 is movable along the cassette track 196 for depositing and retrieving the first cassette 152 from the oven 116 (shown in FIG. 3). The carriage 198 is movable along a longitudinal path of movement, indicated at 200 in FIG. 6.

The cassette carriage 198 includes a carriage base 202 slidably connected to the cassette track 196 and a carriage body 204 extending from the carriage base 202 towards the first end 192. The carriage body 204 is cantilevered off of the carriage base 202 and supported at a distance spaced from the track 164. The first cassette arm 167 further includes an oven load motor 206 attached to the cassette track 196 proximate the second end 194 and operably connected to the carriage base 202.

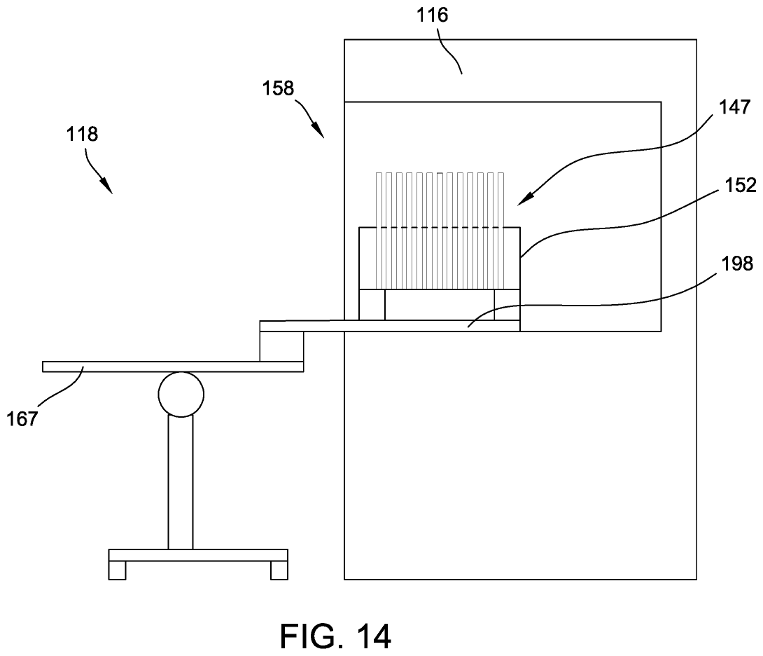

The oven load motor 206 operates to drive the carriage base 202 along the path of movement 208 during oven loading/unloading operations. For example, as shown in FIG. 6, the carriage base 202 is at a first retracted position, and is positioned proximate the second end 194. The oven load motor 206 is operable to drive the carriage base 202 along the path of movement toward the first end 192 of the cassette track 196 to an extended position (shown in FIG. 14). In the extended position, the carriage base 202 is positioned adjacent to the first end 192 with the carriage body 204 extending outward beyond the first end 192 of the cassette track 196. The controller 126 (shown in FIG. 1) provides electrical control signals to each of the motors 170, 186, 206, such that the controller controls each of the motors 170, 186, 206 of the queueing robot 118 and the oven 116 to automatically load and unload wafers at the bond treat station 114.

The first cassette 152 includes a first cassette frame 210 supported on the cassette carriage 198. The first cassette frame 210 includes feet, two side feet 212 and a center foot 214, that are shaped to engage corresponding engagement structures 216 on the carriage body 204. As shown in FIG. 6, the engagement structures 216 engaged by the side feet 212 are transverse prongs that are each received in wedge shaped openings defined by the side feet 212. The engagement structure engaged with the center foot 214 is a notch (not shown) defined in the carriage body 204 proximate the first end 192.

The engagement between the first cassette 152 and the cassette carriage 198 allows for selectively connecting and disconnecting the first cassette 152 from the carriage 198 for loading the cassette 152 into the oven 116.

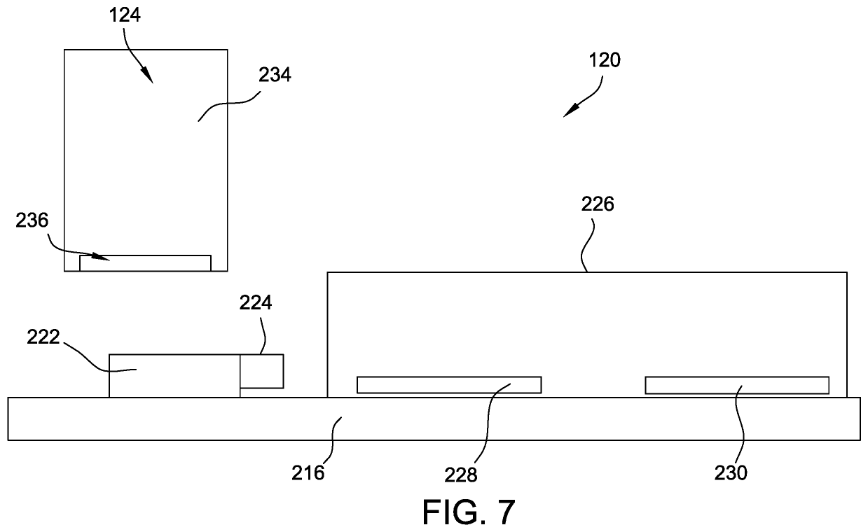

FIG. 7 shows the cleave station 120 of FIG. 1.

The cleave station 120 includes a cleaving platform 216 and a cleave tool 222 positioned on the cleaving platform 216. The cleave tool 222 is a mechanical cleave tool in that it facilitates performing a physical separation of the wafers. The cleave tool 222 includes a blade 224 for separating the bond treated wafers received at the cleave station. The cleaving station 120 further includes a device 226 for aligning the wafers during cleaving.

During use, the transfer robot 112 (shown in FIG. 1) transports bond treated wafers from one of the wafer cassettes 152, 154 (shown in FIG. 3) and deposits them at the cleaving platform 216. The cleaving process is then initiated, in which the alignment tool 226 engages a portion of the wafer and the cleave tool 222 cleaves the wafer along an implant plane to form the separate handle wafer 228 and donor wafer 230.

The cleave station 120 further includes a camera assembly 124 including an inspection box 234. The inspection box 234 defines an internal cavity (not shown) and includes a slot 236 providing access to the internal cavity. After the wafer is cleaved, the handle wafer 228 is moved (e.g., by the transfer robot 112) into the internal cavity via the slot 236 for imaging. A camera (not shown) is positioned within the internal cavity and is operable to image the handle wafer 228 to detect any defects on a surface of the handle wafer 228. Other embodiments may not have a side slot 236 but instead may not have a lower plate on the inspection box 234 allowing the wafer to be imaged when it is placed just below the camera assembly 124. In other embodiments the donor wafer 230 is also imaged using the camera assembly 124.

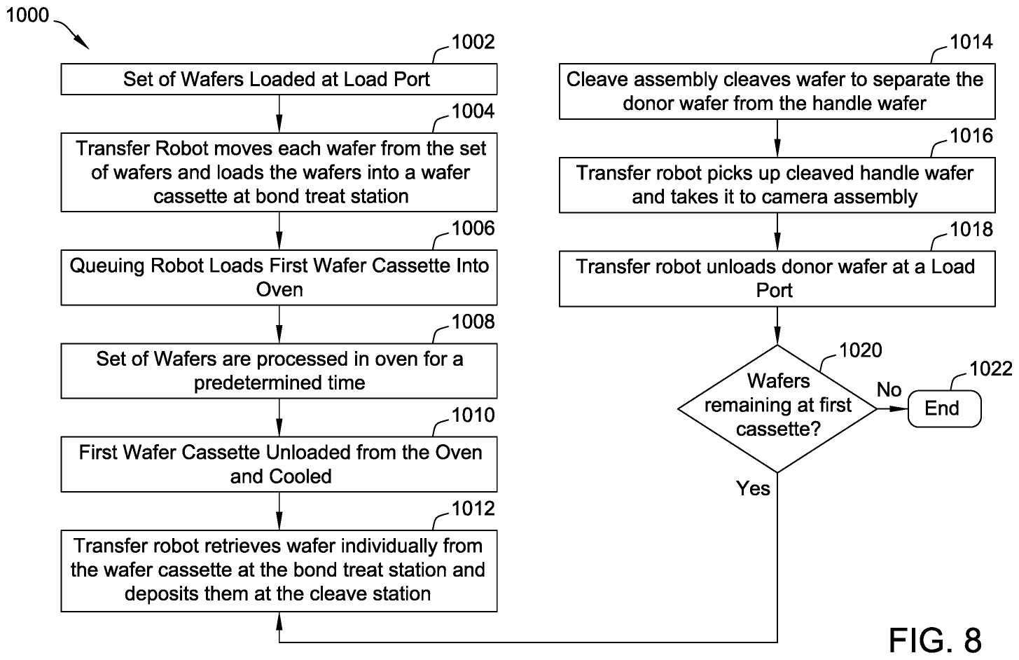

FIG. 8 is a flow diagram showing an example method for processing SOI wafers using the processing system of FIG. 2.

At a first step 1002, a first set of wafers 141 (e.g., twenty-five wafers) are loaded into at least one of the load ports 102, 104, 108, 110. The set of wafers 141 are each of arranged in a vertically stacked configuration and spaced from one another within the pod 140. The wafer pods 140 is positioned on the load platform 136 manually (i.e., by an operator), though in other embodiments the pod 140 may be positioned on the load platform 136 automatically by one or more robots (not shown). As shown in FIG. 9, the first set of wafers 141 are provided in the wafer pod 140 positioned at the load port 102. The pod 140 holds approximately half the number of wafers as the wafer cassette 152.

Referring to FIG. 8, at a second step 1004, the transfer robot 112 moves each wafer from the set of wafers 141 and loads the wafers into a wafer cassette 152 at the bond treat station 114. As shown in FIG. 9, the transfer robot 112 first picks up a first wafer 101 of the set of wafers 141 and moves the wafer 101 to a wafer cassette 152 positioned on the queueing robot 118.

The transfer robot 112 includes a pivotable arm assembly 250 and an extendable base 252. The arm assembly 250 is connected to an end effector 254 and the extendable base 256 and is controlled to position the end effector 254 at least partially within the wafer pod 40 to engage the first wafer 101 with the end effector 254. In some embodiments, the transfer robot 112 includes multiple end effectors (e.g., two or more) to engage and carry multiple wafers simultaneously.

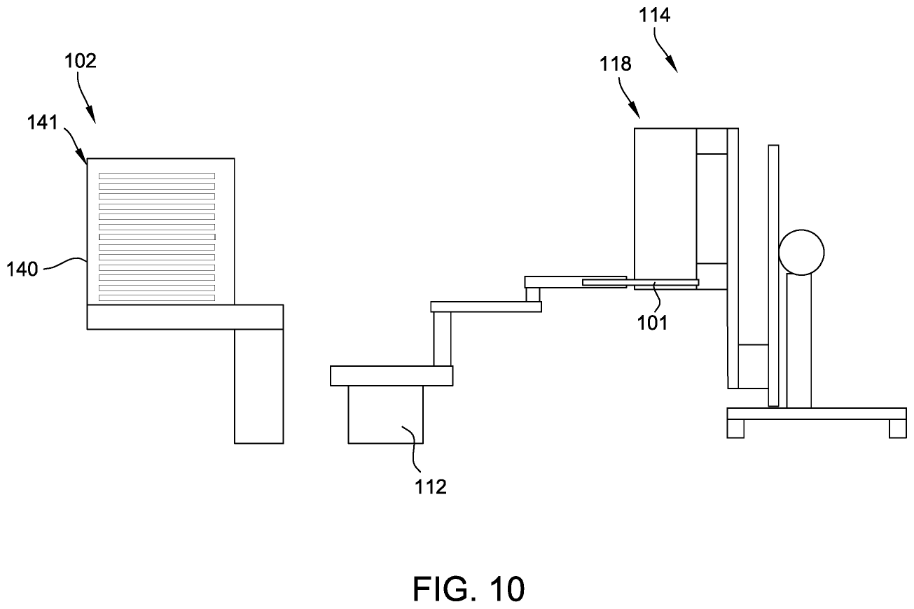

Referring to FIG. 10, the transfer robot 112 is shown carrying a first wafer 101 from the pod 140 to the first cassette 152. The transfer robot 112 deposits the first wafer 101 on a rung (not shown) of the first wafer cassette 152 in the vertical orientation on the queueing robot 118 at the bond treat station 114. The transfer robot 112 then returns to the wafer pod 140 to pick up a second wafer of the set of wafers 141. This process is repeated until each of the wafers from the pod 140 has been moved to the bond treat station 118 and/or until each of the rungs of the wafer cassette 152 are filled. After, or simultaneous with, all twenty-five wafers 141 from the first pod 140 are loaded into the first cassette 152, the transfer robot 112 loads another twenty-five wafers 143 (shown in FIG. 1) from the second pod 142 at the second port 104, as shown in FIG. 11.

Referring back to FIG. 8, after the transfer robot 112 has finished depositing wafers at the first cassette 152, the process proceeds to step 1006. At step 1006, the queueing robot 118 loads the first cassette 152 into the oven 116.

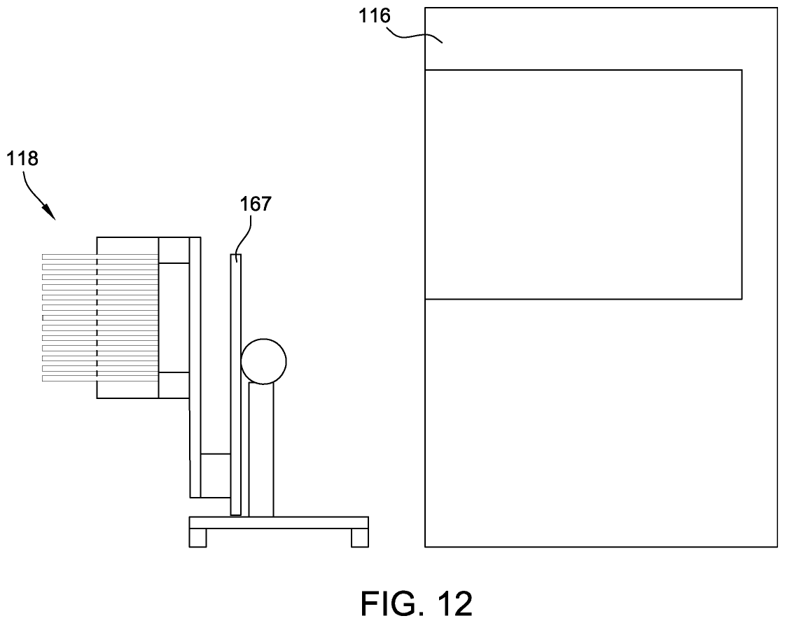

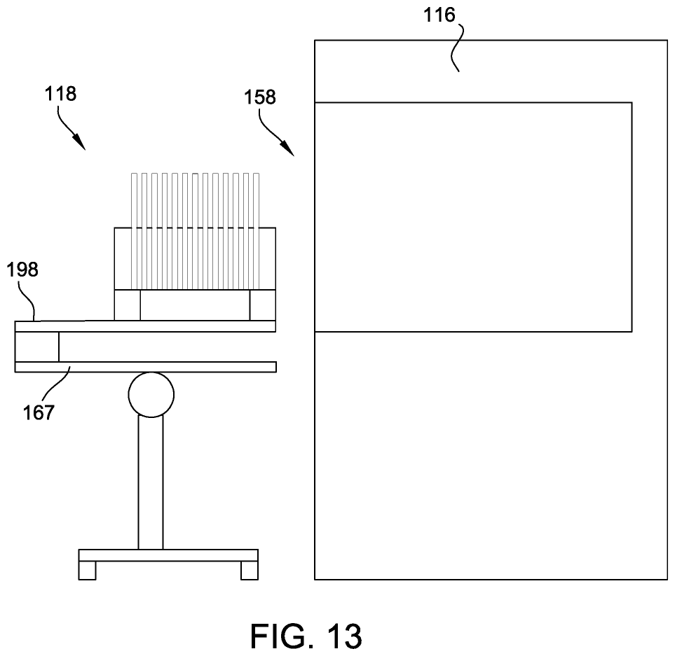

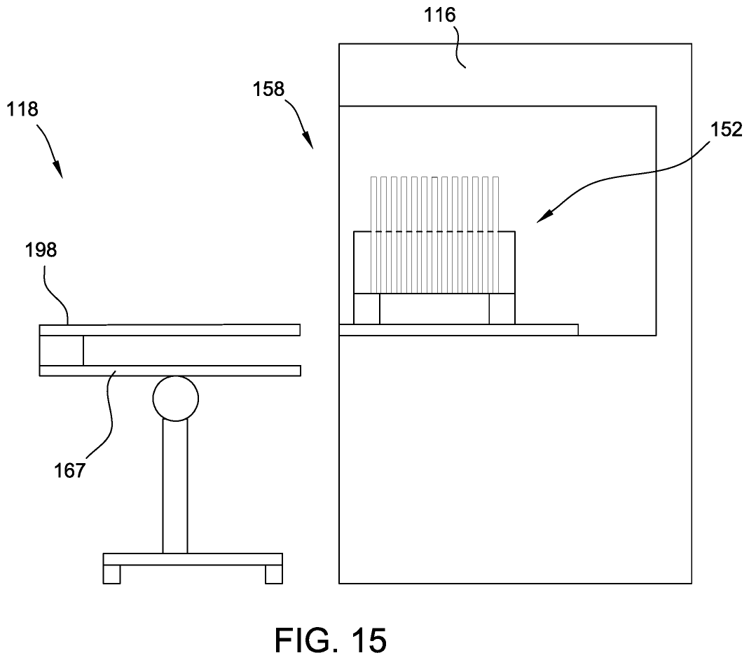

Referring to FIG. 12, at step 1006, the first cassette arm 167 is rotated from the vertical orientation, as shown in FIG. 12, to the horizontal orientation, as shown in FIG. 13, by actuating the first arm drive 182 (shown in FIG. 5). If the first cassette arm 167 is positioned out of lateral alignment with the oven opening 158, the support slide 166 (shown in FIG. 5) may first be laterally moved to align the first cassette arm 167 with the oven opening 158, prior to rotating to the horizontal configuration. The oven load motor 206 (shown in FIG. 6) on the first cassette arm 167 is then actuated to move the carriage 198 from a retracted position, as shown in FIG. 13, to an extended position, shown in FIG. 14, to load the first wafer cassette 152 into the oven 116. After the first wafer cassette 152 is loaded into the oven 116, the carriage 198 is retracted from the oven 116, as shown in FIG. 15, and the first wafer cassette 152 is retained within the oven 116. In some embodiments, the oven 116 may include a clamp, latch, or other mechanism (not shown) to secure cassette 152 in the oven 116 when it is inserted such that, when the carriage 198 is retracted from the oven 116, the engagement features 216 (shown in FIG. 6) on the carriage 167 are caused to disengage from the feet 212, 214 of the first cassette 152, such that the first wafer cassette 152 is retained within the oven.

Referring back to FIG. 8, after the first wafer cassette 152 is loaded, the process proceeds to step 1008 in which the set of wafers 147 are processed in the oven 116 for a predetermined period of time. The oven 116 is heated to a temperature between 250 degrees Celsius and 400 degrees Celsius. The oven door is closed and the wafers 141 are bond treated within the oven 116 for a predetermined time, such as about two hours.

While the first wafer cassette 152 is processed in the oven 116, the transfer robot 112 may fill the second cassette 154 with a second set of wafers 147 (shown in FIG. 3). After the second wafer cassette 154 is filled, the second wafers 147 are held in queue in the second wafer cassette 154 on the queueing robot 118, until the first set of wafers 145 is finished processing (i.e., after the predetermined time period has elapsed), and the first cassette 152 is unloaded from the oven.

At step 1010, the first wafer cassette 152 is unloaded from the oven 116 and cooled. For example, after the predetermined time period has elapsed the first cassette 152 is unloaded from the oven in substantially the same process, except in reverse order, as the oven loading. In some embodiments, the second cassette 154 is then loaded into the oven 116 in substantially the same manner, and the second set of wafers 147 are bond treated within the oven 116. In some embodiments, the first set of wafers 145 are allowed to cool on the queueing robot 118 for a predetermined period of time, such as between five to twenty minutes, or between ten and fifteen minutes. While the first set of wafers 145 are cooled and/or while the wafers 145 are in holding prior to being loaded into the furnace, the first cassette 152 is oriented in a slanted configuration (e.g., about thirty degrees tilted from the vertical configuration) to keep the wafers 145 secured within the cassette 152.

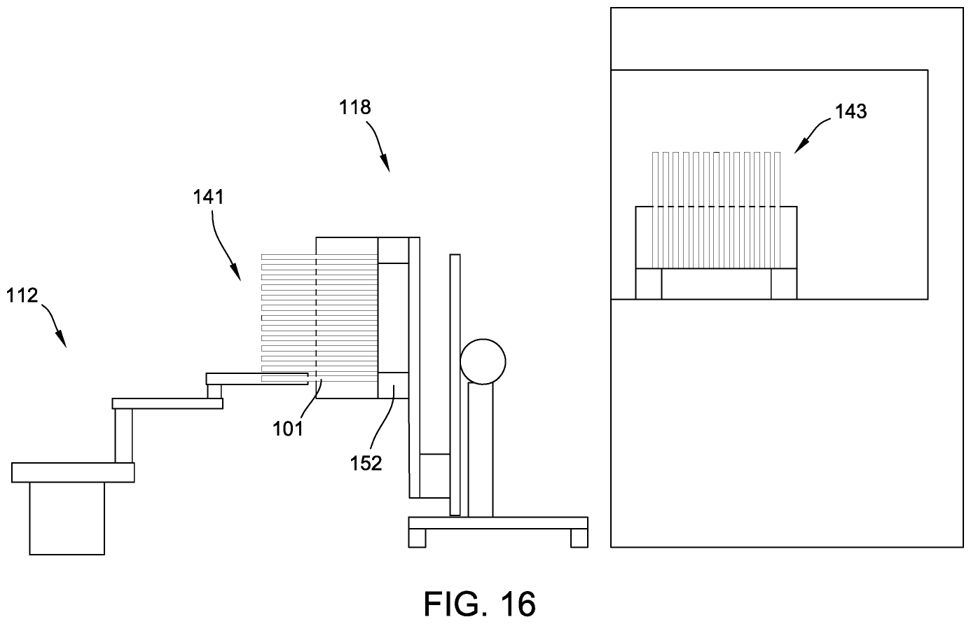

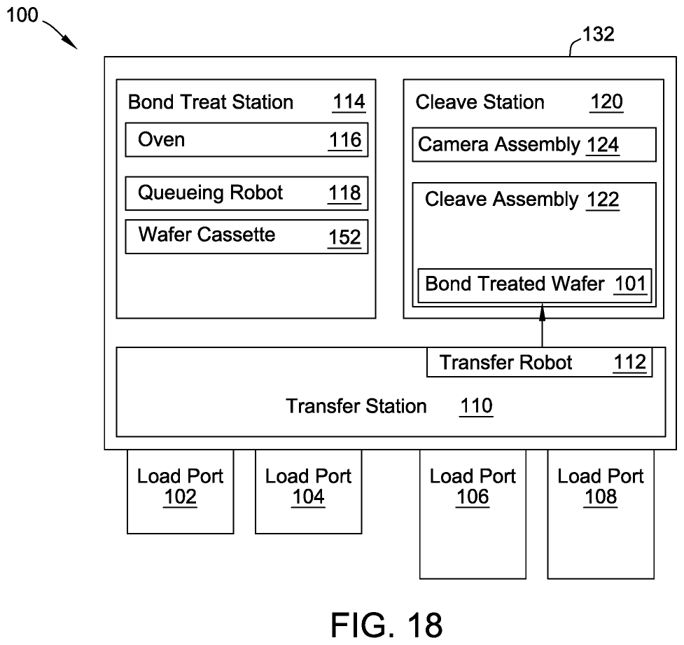

At step 1012, the transfer robot 112 retrieves wafers individually from the bond treat station 114 and moves them to the cleave station 120. For example referring to FIG. 16, after the predetermined period for cooling has elapsed, the transfer robot 112 engages the first wafer 101 on the first wafer cassette 152 and moves the first wafer 101 to the cleave station, as shown in FIGS. 19 and 20. Referring to FIG. 18, the transfer robot 112 moves laterally within the machine frame to carry the first wafer 101, which has been bond treated in the oven, from the first wafer cassette 152 to the cleave assembly 122 at the cleave station 120.

In some embodiments, after the wafers 145 have cooled and prior to being transferred to the cleaving station 120, the transfer robot 112 first transfers the wafers 145 to a notch pre-aligner and/or laser mark reader (not shown).

Referring back to FIG. 8, at step 1014, the cleave assembly 122 cleaves the bond treated wafer 101 to separate a donor wafer 230 from a handle wafer 228. After cleaving, the transfer robot 112 may move the handle wafer 228 to the camera assembly 124 for imaging by the camera.

At step 1016, and as shown in FIG. 19, the transfer robot 112 then engages the handle wafer 228 and unloads the handle wafer 228 into a wafer pod 340 at load port 106. At step 1018, the donor wafer 230 is also moved by the transfer robot 112 from the cleave station 120 to an additional wafer pod 342 at load port 108, as shown in FIG. 19.

Referring back to FIG. 8, at step 1020, if there are still wafers remaining in the first cassette 152, steps 1012-1018 are repeated until all bond treated wafers 147 in the first cassette 152 have been cleaved and unloaded to one of the pods 340, 342. In some embodiments, the pods 140, 142 at the load ports 102, 104, 108, 110 may be switched out for empty pods 140, 142, either manually by an operator or autonomously, midway through cleaving of the first set of wafers 147 to contain the increased number of wafers 147 produced from the cleaving. After all wafers 147 from the first cassette 152 have been processed, the method proceeds to an end at step 1022.

The method of FIG. 8 shows an example flow of processing a single set of wafers. As described herein, the process may be continuously run using the system 100 such that at least one set of wafers are being bond treated while a different set of wafers are being cleaved. For example, after step 1020, the process may proceed to back to step 1010, at which a second wafer cassette is removed from the oven, after the predetermined bond treatment time has elapsed, and steps 1010-1020 are repeated for the second set of wafers.

The system 100 of the present application is able to cleave all wafers from a given set within a predetermined dwell after bond treatment. As used herein, the phrase “dwell time” is defined as the time between the bond treatment of a set of wafers is ended (e.g., the time the set of wafers are unloaded from the oven), and the time the last wafer of the set of wafers is cleaved.

Higher dwell times in production have been found to reduce the quality of produced wafers. In particular, increased dwell times have been found to cause defects during cleaving, such as partial layer transfers of the donor wafer to the handle wafer. The system 100 of the present application is controlled such that the dwell time for a set of wafers is no greater than the maximum dwell time to reduce the potential for errors during cleaving. For example, the system may be controlled such that the dwell time during processing is minimized and/or does not exceed a maximum of two hours, three hours, or four hours.

The system provides an advantage over known wafer processing systems, which rely on manual operator operations between bond treatment and cleaving of the wafers, in that the wafers are each automatically transferred from the bond treatment station and cleaved at the cleaving station. As a result, the systems and methods described herein provide greater control and reduced variability over the dwell time between bond treatment and cleaving, and thus provide for improved and more consistent wafer quality. Additionally, the systems and methods described herein reduced overall dwell times during processing.

In some embodiments, the above-described systems and methods are electronically or computer controlled. The embodiments described herein are not limited to any particular system controller or processor for performing the processing tasks described herein. The term “controller” or “processor”, as used herein, is intended to denote any machine capable of performing the calculations, or computations, necessary to perform the tasks described herein. The terms “controller” and “processor” also are intended to denote any machine capable of accepting a structured input and of processing the input in accordance with prescribed rules to produce an output. It should also be noted that the phrase “configured to” as used herein means that the controller/processor is equipped with a combination of hardware and software for performing the tasks of embodiments of the disclosure, as will be understood by those skilled in the art. The terms “controller” and “processor”, as used herein, refers to central processing units, microprocessors, microcontrollers, reduced instruction set circuits (RISC), application specific integrated circuits (ASIC), logic circuits, and any other circuit or processor capable of executing the functions described herein.

The computer implemented embodiments described herein embrace one or more computer readable media, including non-transitory computer readable storage media, wherein each medium may be configured to include or includes thereon data or computer executable instructions for manipulating data. The computer executable instructions include data structures, objects, programs, routines, or other program modules that may be accessed by a processing system, such as one associated with a general-purpose computer capable of performing various different functions or one associated with a special-purpose computer capable of performing a limited number of functions. Aspects of the disclosure transform a general-purpose computer into a special-purpose computing device when configured to execute the instructions described herein. Computer executable instructions cause the processing system to perform a particular function or group of functions and are examples of program code means for implementing steps for methods disclosed herein. Furthermore, a particular sequence of the executable instructions provides an example of corresponding acts that may be used to implement such steps. Examples of computer readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), or any other device or component that is capable of providing data or executable instructions that may be accessed by a processing system.

A computer or computing device such as described herein has one or more processors or processing units, system memory, and some form of computer readable media. By way of example and not limitation, computer readable media comprise computer storage media and communication media. Computer storage media include volatile and nonvolatile, removable and non-removable media implemented in any method or technology for storage of information such as computer readable instructions, data structures, program modules or other data. Communication media typically embody computer readable instructions, data structures, program modules, or other data in a modulated data signal such as a carrier wave or other transport mechanism and include any information delivery media. Combinations of any of the above are also included within the scope of computer readable media.

The example methods do not require the particular order of steps, or sequential order. In addition, other steps may be included, or steps may be eliminated, from the described methods, and other components may be added to, or removed from, the described systems. It will be appreciated that the above embodiments that have been described in particular detail are merely example or possible embodiments, and that there are many other combinations, additions, or alternatives.

Also, the particular naming of the components, capitalization of terms, the attributes, data structures, or any other programming or structural aspect is not mandatory or significant, and the mechanisms that implement the disclosure or its features may have different names, formats, or protocols. Further, the system may be implemented via a combination of hardware and software, as described, or entirely in hardware elements. Also, the particular division of functionality between the various system components described herein is merely one example, and not mandatory; functions performed by a single system component may instead be performed by multiple components, and functions performed by multiple components may instead performed by a single component.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Various changes, modifications, and alterations in the teachings may be contemplated by those skilled in the art without departing from the intended spirit and scope thereof. It is intended that the present disclosure encompass such changes and modifications.

This written description uses examples to describe the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A semiconductor wafer processing system for processing a set of semiconductor wafers, the system comprising:
a bond treat station including an oven;
a cleave station including a cleave assembly for cleaving the wafer;
a transfer robot; and
a controller for controlling the transfer robot, wherein the controller is programmed to:
control the transfer robot to retrieve a first wafer of the set of semiconductor wafers from the bond treat station; and
control the transfer robot to deliver the first wafer to the cleave station for processing by the cleave assembly.

2. The semiconductor wafer processing system of claim 1 further comprising a machine frame, wherein the bond treat station, the cleave station, and the transfer robot are each at least partially positioned within the machine frame.

3. The semiconductor wafer processing system of claim 1, wherein the bond treat station further includes a queueing robot for holding a first cassette, wherein the transfer robot retrieves the first wafer from the first cassette at the bond treat station.

4. The semiconductor wafer processing system of claim 3, wherein the queueing robot incudes a first cassette arm for holding the first cassette thereon, the first cassette arm being pivotable between a first orientation and a second orientation for loading the first cassette into the oven.

5. The semiconductor wafer processing system of claim 3, wherein the queueing robot includes a first cassette arm, the first cassette arm including a carriage and the first cassette being slidably attached to the carriage, the carriage being moveable on the first cassette arm between a retracted position and an extended position.

6. The semiconductor wafer processing system of claim 5, wherein the controller is programmed to:
control the transfer robot to deliver the first wafer to a first cassette on the first cassette arm while the first cassette arm is in a first orientation;
control the first cassette arm to pivot to a second orientation; and
control the carriage to move to the extended position after the first cassette arm is pivoted to the second orientation to load the first cassette into the oven.

7. The semiconductor wafer processing system of claim 5, wherein the queueing robot includes:
a track;
a support slide slidably connected to the track; and
a second cassette arm holding a second cassette thereon, the first cassette arm and the second cassette arm each being pivotably connected to the support slide.

8. The semiconductor wafer processing system of claim 7, wherein the queueing robot further includes a motor operably connected to the support slide, and wherein the controller is programmed to control the motor to move the support slide to align at least one of the first cassette arm and the second cassette arm with an opening of the oven.

9. The semiconductor wafer processing system of claim 1 further comprising a load port, wherein the first wafer is a bonded pair wafer, and wherein the controller is further programmed to:
control the cleave assembly to cleave the first wafer to separate a handle wafer of the bonded pair from a donor wafer; and
control the transfer robot to deliver the handle wafer to a wafer pod at the load port.

10. The semiconductor wafer processing system of claim 1, wherein the cleave assembly includes a mechanical cleave tool.

11. The semiconductor wafer processing system of claim 1, wherein the controller is further programmed to:
control the transfer robot to retrieve the first wafer from a wafer pod at a load port of the processing system;
control the transfer robot to deliver the first wafer to a wafer cassette at the bond treat station; and
control a queueing robot to load the wafer cassette into the oven at the bond treat station, wherein the controller controls the transfer robot to retrieve the first wafer from the bond treat station after the first wafer is processed in the oven.

12. The semiconductor wafer processing system of claim 1, wherein the controller is programmed to:
control the transfer robot to deliver each wafer from the set of wafers to the cleave station; and
control the cleave assembly to cleave each wafer of the set of wafers within a predefined maximum dwell time.

13. The semiconductor wafer processing system of claim 12, wherein the predefined maximum dwell time is less than four hours.

14. A method for processing a set of semiconductor wafers comprising:
retrieving, by a transfer robot, a first bonded pair wafer of the set of semiconductor wafers from a bond treat station, the bond treat station including an oven;
delivering, by the transfer robot, the first bonded pair wafer to a cleave station, the cleave station including a cleave assembly; and
cleaving, by the cleave assembly, the first bonded pair wafer.

15. The method of claim 14, wherein the bond treat station further includes a queueing robot for holding a first cassette, wherein the transfer robot retrieves the first bonded pair wafer from the first cassette at the bond treat station.

16. The method of claim 15, wherein the queueing robot incudes a first cassette arm for holding the first cassette thereon, the first cassette arm being pivotable between a first orientation and a second orientation for loading the first cassette into the oven.

17. The method of claim 15, wherein the queueing robot includes a first cassette arm, the first cassette arm including a carriage and the first cassette being slidably attached to the carriage, the carriage being moveable on the first cassette arm between a retracted position and an extended position, and wherein the method further includes:
delivering, by the transfer robot, the first bonded pair wafer to a cassette on the first cassette arm while the first cassette arm is in a first orientation;
rotating the first cassette arm to a second orientation; and
moving the carriage to the extended position with the first cassette arm in the second orientation to load a first cassette.

18. The method of claim 17, wherein the queueing robot includes a track, a support slide slidably connected to the track, a second cassette arm holding a second cassette thereon, the first cassette arm and the second cassette arm each being pivotably connected to the support slide, and wherein the method further includes moving the support slide to align at least one of the first cassette arm and the second cassette arm with an opening of the oven.

19. The method of claim 14 further comprising:
cleaving, by the cleave assembly, the first bonded pair wafer to separate a handle wafer from a donor wafer; and
delivering, by the transfer robot, the handle wafer to a wafer pod at a load port.

20. The method of claim 14 further comprising:
delivering, by the transfer robot, each wafer from the set of wafers to the cleave station; and
cleaving, by the cleave assembly, each wafer of the set of wafers within a predefined maximum dwell time.
